(19) United States
(12) Patent Application Publication
(10) Pub. No.: US 2025/0079158 A1
(43) Pub. Date: Mar. 6, 2025

(54) METHOD FOR MANUFACTURING SEMICONDUCTOR DEVICE

(71) Applicant: SUMITOMO ELECTRIC INDUSTRIES, LTD., Osaka (JP)

(72) Inventor: Takahide HIRASAKI, Osaka (JP)

(21) Appl. No.: 18/797,904

(22) Filed: Aug. 8, 2024

(30) Foreign Application Priority Data
Aug. 31, 2023 (JP) 2023-141125

(51) Int. Cl. H01L 21/02; H01L 21/28; H01L 29/66

(52) U.S. Cl. CPC H01L 21/02247; H01L 21/28264; H01L 21/02164; H01L 21/02178; H01L 21/02181; H01L 21/02189; H01L 21/02192; H10D 30/015

(57) ABSTRACT

A method for manufacturing a semiconductor device includes forming, on a nitride semiconductor layer, a dielectric oxide film having a higher relative dielectric constant than silicon dioxide, forming a dielectric oxynitride film by nitriding the dielectric oxide film, and forming a gate electrode on the dielectric oxynitride film. The forming the dielectric oxynitride film includes disposing a substrate including the nitride semiconductor layer and the dielectric oxide film inside a reaction furnace including a catalyst metal therein, thermally decomposing an ammonia gas inside the reaction furnace to generate a dinitrogen monoxide gas from nitrogen atoms included in the ammonia gas and oxygen atoms diffused from the dielectric oxide film, and thermally decomposing the dinitrogen monoxide gas to generate a nitrogen monoxide gas.

### CROSS-REFERENCE TO RELATED APPLICATIONS

This application is based upon and claims priority to Japanese Patent Application No. 2023-141125, filed on Aug. 31, 2023, the entire contents of which are incorporated herein by reference.

### TECHNICAL FIELD

The present disclosure relates to methods for manufacturing semiconductor devices.

### BACKGROUND

A conventionally proposed high electron mobility transistor (HEMT) uses a hafnium silicate film having a high relative dielectric constant as a gate insulating film, in order to improve a drain current.

Related art include Japanese Laid-Open Patent Publication No. 2009-506537, and Japanese Laid-Open Patent Publication No. H05-223855, for example.

In recent years, there are increasing demands to reduce a gate leakage.

### SUMMARY

It is an object in one aspect of the present disclosure to provide a method for manufacturing a semiconductor device capable of reducing the gate leakage.

According to one aspect of the present disclosure, a method for manufacturing a semiconductor device includes forming a dielectric oxide film on a nitride semiconductor layer, the dielectric oxide film having a higher relative dielectric constant than silicon dioxide; forming a dielectric oxynitride film by nitriding the dielectric oxide film; and forming a gate electrode on the dielectric oxynitride film, wherein the forming the dielectric oxynitride film includes disposing a substrate including the nitride semiconductor layer and the dielectric oxide film inside a reaction furnace including a catalyst metal therein; thermally decomposing an ammonia gas inside the reaction furnace to generate a dinitrogen monoxide gas from nitrogen atoms included in the ammonia gas and oxygen atoms diffused from the dielectric oxide film; and thermally decomposing the dinitrogen monoxide gas to generate a nitrogen monoxide gas.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view (part 1) illustrating a method for manufacturing a semiconductor device according to an embodiment;

FIG. 2 is a cross sectional view (part 2) illustrating the method for manufacturing the semiconductor device according to the embodiment;

FIG. 3 is a cross sectional view (part 3) illustrating the method for manufacturing the semiconductor device according to the embodiment;

FIG. 4 is a cross sectional view (part 4) illustrating the method for manufacturing the semiconductor device according to the embodiment;

FIG. 5 is a cross sectional view (part 5) illustrating the method for manufacturing the semiconductor device according to the embodiment;

FIG. 6 is a cross sectional view (part 6) illustrating the method for manufacturing the semiconductor device according to the embodiment;

FIG. 7 is a cross sectional view (part 7) illustrating the method for manufacturing the semiconductor device according to the embodiment;

FIG. 8 is a cross sectional view (part 8) illustrating the method for manufacturing the semiconductor device according to the embodiment;

FIG. 9 is a cross sectional view (part 1) illustrating a reaction furnace used for nitriding a dielectric oxide film;

FIG. 10 is a cross sectional view (part 2) illustrating the reaction furnace used for nitriding the dielectric oxide film; and

FIG. 11 is a diagram illustrating a relationship between a flow rate of ammonia gas and a degree of nitridation of the dielectric oxide film.

### DETAILED DESCRIPTION

### Description of Embodiments of the Present Disclosure

First, embodiments of the present disclosure will be described in the following.
[1] A method for manufacturing a semiconductor device according to an embodiment of the present disclosure includes forming a dielectric oxide film on a nitride semiconductor layer, the dielectric oxide film having a higher relative dielectric constant than silicon dioxide; forming a dielectric oxynitride film by nitriding the dielectric oxide film; and forming a gate electrode on the dielectric oxynitride film, wherein the forming the dielectric oxynitride film includes disposing a substrate including the nitride semiconductor layer and the dielectric oxide film inside a reaction furnace including a catalyst metal therein; thermally decomposing an ammonia gas inside the reaction furnace to generate a dinitrogen monoxide gas from nitrogen atoms included in the ammonia gas and oxygen atoms diffused from the dielectric oxide film; and thermally decomposing the dinitrogen monoxide gas to generate a nitrogen monoxide gas.

The dielectric oxynitride film functions as a gate insulating film. The dielectric oxynitride film has a higher insulation and a higher withstand voltage than the dielectric oxide film, and can thus reduce a gate leakage. Further, because the catalyst metal is provided inside the reaction furnace, the ammonia gas may be used as a nitrogen source to be supplied to the reaction furnace, and it is unnecessary to supply the dinitrogen monoxide and the dinitrogen monoxide gas to the reaction furnace.
[2] In [1] above, the dielectric oxide film may include at least one element selected from a group consisting of hafnium, lanthanum, and zirconium. In this case, a high relative dielectric constant can easily be obtained for the dielectric oxynitride film.
[3] In [2] above, the dielectric oxide film may include at least one element selected from a group consisting of silicon and aluminum. In this case, a high relative dielectric constant can easily be obtained for the dielectric oxynitride film.
[4] In any one of [1] to [3] above, a surface of the nitride semiconductor layer opposing the dielectric oxide film may have a nitrogen polarity. In this case, a low resistance can easily be achieved.
[5] In any one of [1] to [4] above, the forming the dielectric oxynitride film may include setting a temperature inside the reaction furnace in a range of 600° C. or more and 800° C. or less. In this case, nitridation of the dielectric oxide film can easily be advanced, and crystallization of the dielectric oxynitride film can be prevented.
[6] In any one of [1] to [5] above, the forming the dielectric oxynitride film may supply the ammonia gas into the reaction furnace at a flow rate of 100 sccm or more. In this case, nitridation of the dielectric oxide film can easily be advanced.
[7] In any one of [1] to [6] above, the reaction furnace may include a nozzle supplied with the ammonia gas, and the catalyst metal may be present at least on a surface of the nozzle. In this case, the ammonia gas can easily be thermally decomposed on the surface of the nozzle.
[8] In any one of [1] to [7] above, the reaction furnace may include a substrate holder on which the substrate is placed, and the catalyst metal may be present at least on a surface of the substrate holder. In this case, the ammonia gas can easily be thermally decomposed on the surface of the substrate holder.
[9] In any one of [1] to [8] above, the reaction furnace may include a substrate holder on which the substrate is placed, and a jig configured to support the substrate holder, and the catalyst metal may be present at least on a surface of the jig. In this case, the ammonia gas can easily be thermally decomposed on the surface of the jig.
[10] In any one of [1] to [9] above, the reaction furnace may include a substrate holder on which the substrate is placed, a jig configured to support the substrate holder, and a dummy member supported by the jig, and the catalyst metal may be present at least on a surface of the dummy member. In this case, the ammonia gas easily be thermally decomposed on the surface of the dummy member.
[11] In any one of [1] to [10] above, the reaction furnace may include a chamber having the catalyst metal provided at least on an inner surface thereof. In this case, the ammonia gas can easily be thermally decomposed on the inner surface of the chamber.
[12] In any one of [1] to [6] above, the reaction furnace may include a shower head supplied with the ammonia gas, and the catalyst metal may be present at least on a surface of the shower head. In this case, the ammonia gas can easily be thermally decomposed on the surface of the shower head.
[13] In any one of [1] to [12] above, the forming the dielectric oxynitride film may supply a nitrogen gas into the reaction furnace together with the ammonia gas. In this case, it is possible to prevent the supply of excess ammonia gas.
[14] In [13] above, the ammonia gas and the nitrogen gas may account for 95 vol % or more of gases supplied into the reaction furnace by the forming the dielectric oxynitride film. In this case, it is possible to prevent the supply of unnecessary gases, such as the dinitrogen monoxide gas and the nitrogen monoxide gas.

### Details of Embodiments of the Present Disclosure

Hereinafter, embodiments of the present disclosure will be described in detail, but the present disclosure is not limited thereto. In the present specification and the drawings, constituent elements or components having substantially the same functional configuration are designated by the same reference numerals, and a redundant description thereof may be omitted. In the present disclosure, “a plan view” of an object refers to a view of the object viewed from above the object.

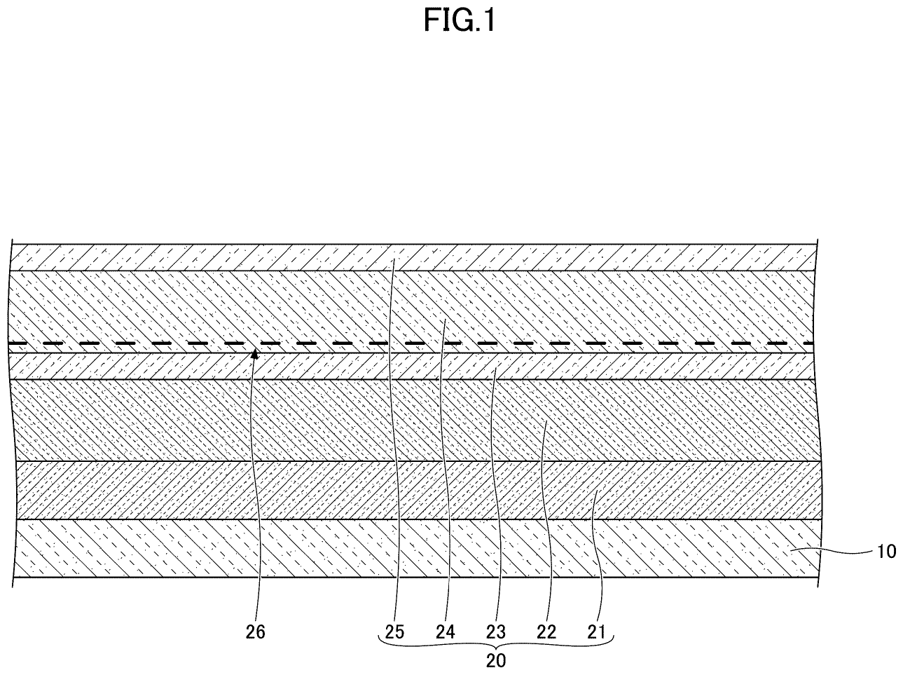

The embodiments relate to a method for manufacturing a semiconductor device including a GaN-based high electron mobility transistor (HEMT). FIG. 1 through FIG. 8 are cross sectional views illustrating the method for manufacturing the semiconductor device according to an embodiment.

First, as illustrated in FIG. 1, a nitride semiconductor layer 20 is formed on a growth substrate 10 by metal organic chemical vapor deposition (MOCVD), for example. When forming the nitride semiconductor layer 20, a buffer layer 21, a barrier layer 22, a spacer layer 23, a channel layer 24, and a cap layer 25 are successively formed in this order.

The growth substrate 10 is a semi-insulating silicon carbide (SiC) substrate, for example. In the case where the growth substrate 10 is the SiC substrate, an upper surface of the growth substrate 10 is a carbon (C) polar face. In the case where the upper surface of the growth substrate 10 is the C polar face, crystal growth of the nitride semiconductor layer 20 can be achieved using a nitrogen (N) polar face as a growth surface.

The buffer layer 21 is formed on the growth substrate 10. The buffer layer 21 is an aluminum nitride (ALN) layer, for example. The AlN layer has a thickness in a range of 5 nm or more and 100 nm or less, for example. The buffer layer 21 may include an AlN layer, and a gallium nitride (GaN) layer or an aluminum gallium nitride (AlGaN) layer formed on the ALN layer.

The barrier layer 22 is formed on the buffer layer 21. The barrier layer 22 is an AlGaN layer, for example. A band gap of the barrier layer 22 is larger than a band gap of the channel layer 24. The barrier layer 22 has a thickness in a range of 5 nm or more and 50 nm or less, for example. A composition of the barrier layer 22 is Al_{Y}Ga_{1-Y}N (0.15<=Y<=0.55), for example. A conductivity type of the barrier layer 22 is n-type or undoped (i-type), for example. An indium aluminum nitride (InAlN) layer or an indium aluminum gallium nitride (InAlGaN) layer may be used in place of the AlGaN layer.

The spacer layer 23 is formed on the barrier layer 22. The spacer layer 23 is an AlN layer, for example. The spacer layer 23 has a thickness in a range of 0.5 nm or more and 3.0 nm or less, for example.

The channel layer 24 is formed on the spacer layer 23. The channel layer 24 is a GaN layer, for example. The band gap of the channel layer 24 is smaller than the band gap of the barrier layer 22. The channel layer 24 has a thickness in a range of 5 nm or more and 30 nm or less, for example. Strain is generated between the channel layer 24 and the barrier layer 22, and between the channel layer 24 and the spacer layer 23 due to the different lattice constants thereof, and the strain induces a piezoelectric charge at an interfaces between the channel layer 24 and the barrier layer 22, and at an interface between the channel layer 24 and the spacer layer 23. Hence, a two-dimensional electron gas (2DEG) is generated in the channel layer 24 in a vicinity of the surface opposing the barrier layer 22, thereby forming a channel region 26. The conductivity type of the channel layer 24 is the n-type or undoped (i-type), for example.

The cap layer 25 is formed on the channel layer 24. The cap layer 25 is an AlGaN layer, for example. The cap layer 25 has a thickness in a range of 1 nm or more and 5 nm or less, for example.

Crystal growth of the buffer layer 21, the barrier layer 22, the spacer layer 23, the channel layer 24, and the cap layer 25 occur using N polar faces thereof as the growth surface, on the C polar face of the SiC substrate. Accordingly, each of the buffer layer 21, the barrier layer 22, the spacer layer 23, the channel layer 24, and the cap layer 25 has an upper surface with the nitrogen (N) polarity, and each of the buffer layer 21, the barrier layer 22, the spacer layer 23, the channel layer 24, and the cap layer 25 has a lower surface with a gallium (Ga) polarity.

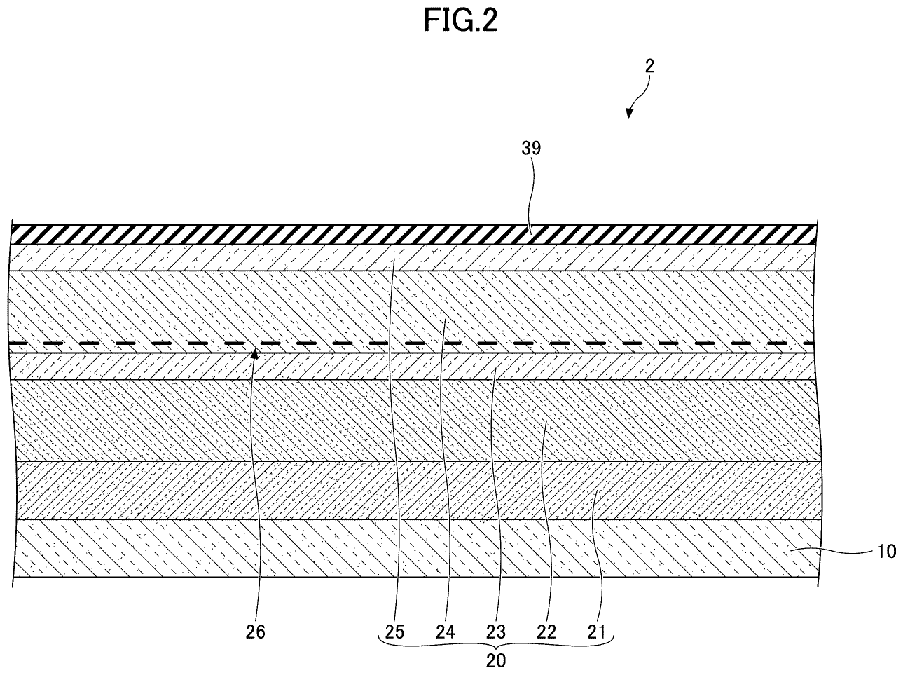

Next, as illustrated in FIG. 2, a dielectric oxide film 39 is formed on the nitride semiconductor layer 20. The dielectric oxide film 39 can be formed by an atomic layer deposition (ALD), for example. The dielectric oxide film 39 makes contact with an upper surface of the nitride semiconductor layer 20. A relative dielectric constant of the dielectric oxide film 39 is higher than that of silicon dioxide (SiO₂). The dielectric oxide film 39 is a high dielectric constant film. The dielectric oxide film 39 may include at least one element selected from a group consisting of hafnium (Hf), lanthanum (La), and zirconium (Zr). In addition, the dielectric oxide film 39 may include at least one element selected from a group consisting of silicon (Si) and aluminum (Al). For example, the dielectric oxide film 39 is a hafnium silicate (HfSiO_{X}) film or a hafnium aluminate (HfAlO_{X}) film. The dielectric oxide film 39 has a thickness in a range of 5 nm or more and 30 nm or less, for example.

Accordingly, a substrate 2 including the growth substrate 10, the nitride semiconductor layer 20, and the dielectric oxide film 39 is obtained. In the substrate 2, the surface of the nitride semiconductor layer 20 opposing the dielectric oxide film 39 has the N polarity.

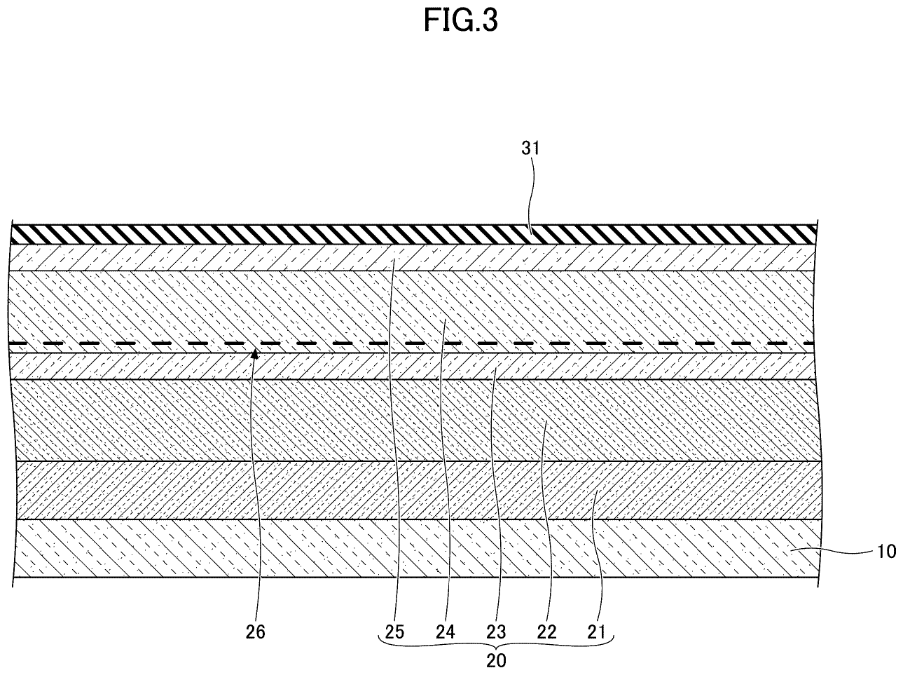

Next, as illustrated in FIG. 3, nitridation of the dielectric oxide film 39 is performed to form a dielectric oxynitride film 31. A relative dielectric constant of the dielectric oxynitride film 31 is higher than that of the SiO₂. The dielectric oxynitride film 31 is a high dielectric constant film. The dielectric oxynitride film 31 may include at least one element selected from the group consisting of Hf, La, and Zr. In addition, the dielectric oxynitride film 31 may include at least one element selected from the group consisting of Si and Al. For example, the dielectric oxynitride film 31 is a hafnium silicon oxynitride (HfSiON) film or a hafnium aluminum oxynitride (HfAlON) film. Details of a method for nitriding the dielectric oxide film 39 will be described later.

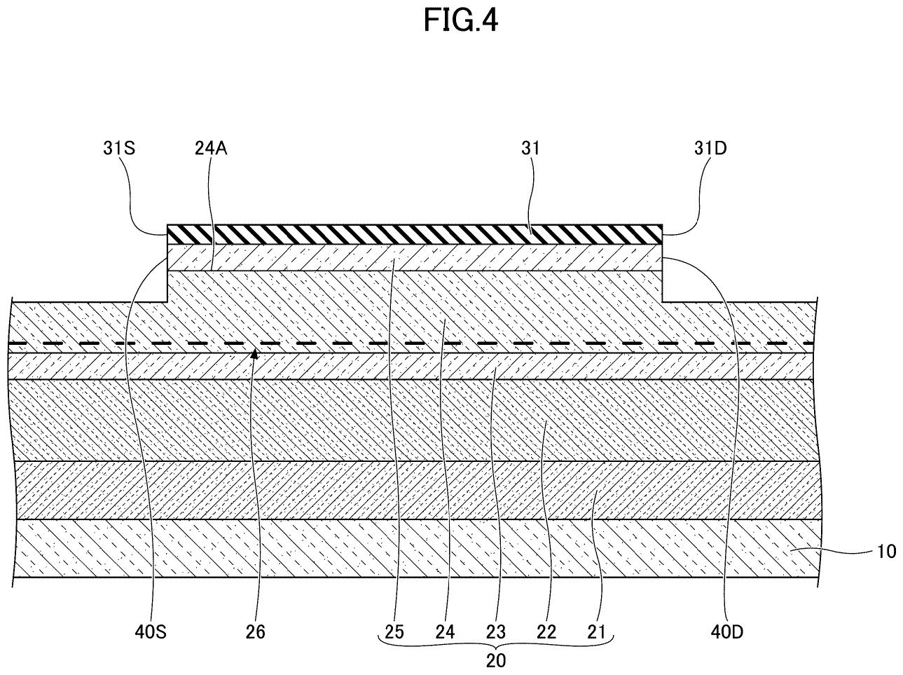

Next, as illustrated in FIG. 4, an opening 31S for a source and an opening 31D for a drain are formed in the dielectric oxynitride film 31, and a recess 40S for the source and a recess 40D for the drain are formed in the nitride semiconductor layer 20. A bottom of the recess 40S and a bottom of the recess 40D may be closer to a lower surface of the channel layer 24 than an upper surface 24A of the channel layer 24. That is, the recess 40S and the recess 40D may be formed deeper than the upper surface 24A of the channel layer 24. The bottom of the recess 40S and the bottom of the recess 40D may be in the channel layer 24, or in the spacer layer 23, or in the barrier layer 22.

The opening 31S, the opening 31D, the recess 40S, and the recess 40D can be formed by reactive ion etching (RIE) using a mask (not illustrated), for example. For example, a chlorine-based (Cl-based) gas is used as a reactive gas when forming the opening 31S, the opening 31D, the recess 40S, and the recess 40D.

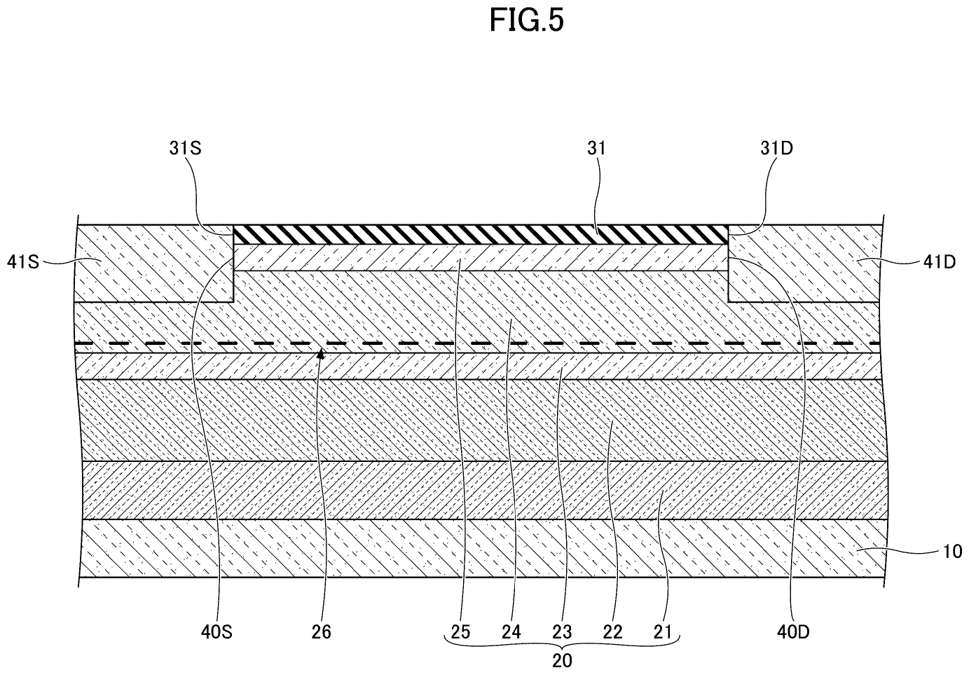

Next, as illustrated in FIG. 5, a regrowth layer 41S is formed on the channel layer 24, the spacer layer 23, or the barrier layer 22 inside the recess 40S, and a regrowth layer 41D is formed on the channel layer 24, the spacer layer 23, or the barrier layer 22 inside the recess 40D. The regrowth layer 41S and the regrowth layer 41D are n-type GaN layers, for example. The regrowth layer 41S and the regrowth layer 41D include germanium (Ge) or Si as an n-type impurity. Electrical resistances of the regrowth layer 41S and the regrowth layer 41D are lower than an electrical resistance of the channel layer 24. The regrowth layer 41S and the regrowth layer 41D can be formed by physical vapor deposition (PVD), such as vapor deposition, sputtering, molecular beam epitaxy (MBE), or the like, for example.

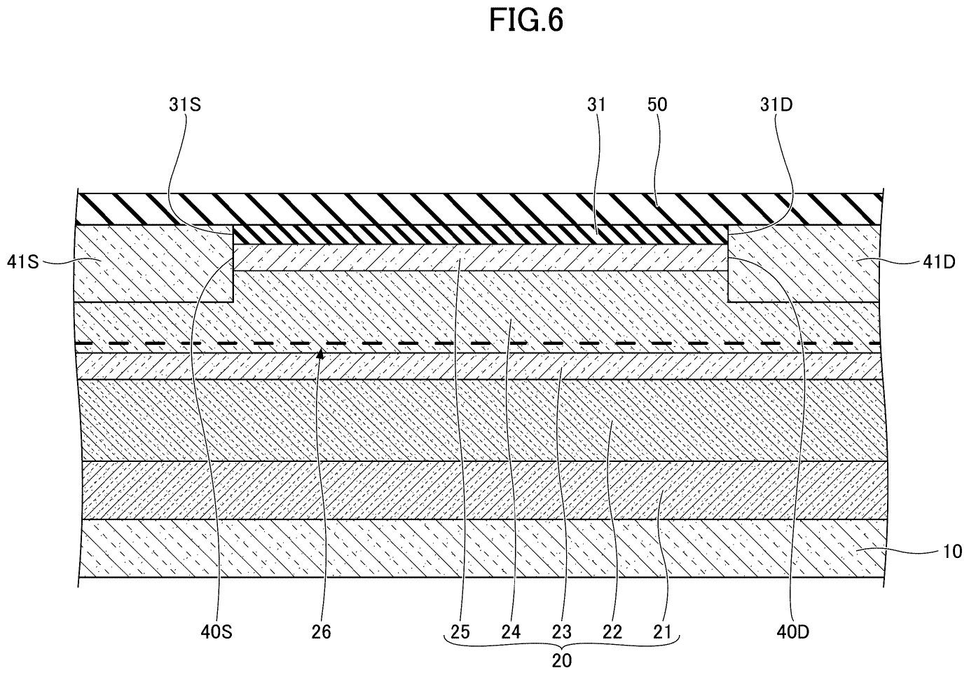

Next, as illustrated in FIG. 6, a passivation film 50 is formed on the dielectric oxynitride film 31, the regrowth layer 41S, and the regrowth layer 41D. The passivation film 50 covers the dielectric oxynitride film 31, the regrowth layer 41S, and the regrowth layer 41D. The passivation film 50 is a silicon nitride (SiN) film, for example. The passivation film 50 has a thickness in a range of 5 nm or more and 50 nm or less, for example.

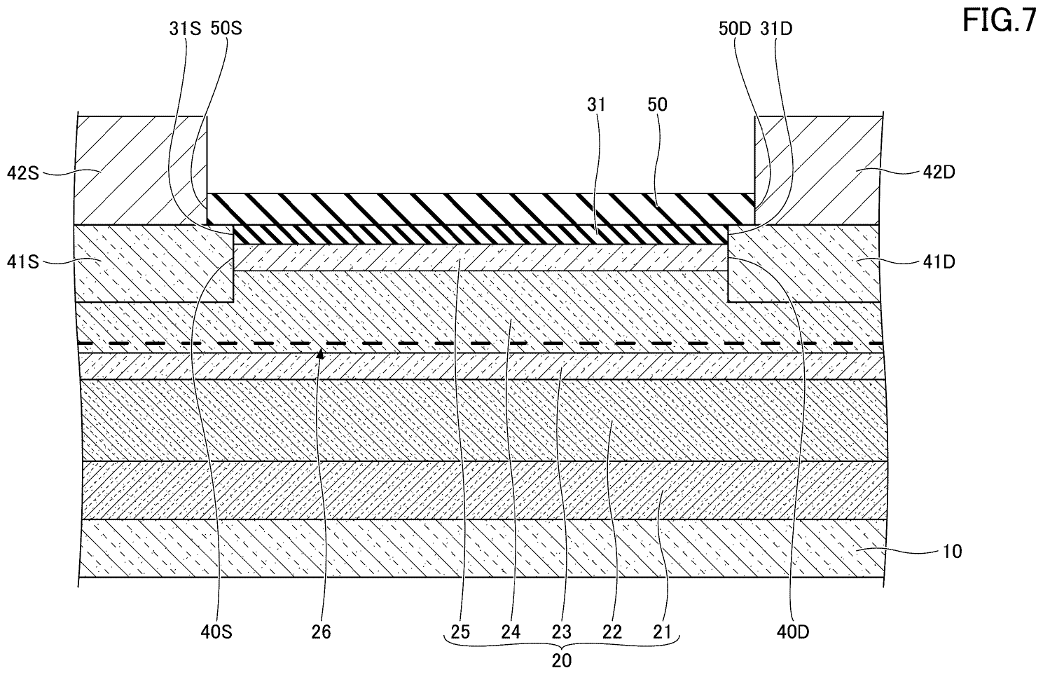

Next, as illustrated in FIG. 7, an opening 50S for the source and an opening 50D for the drain are formed in the passivation film 50. The opening 50S and the opening 50D can be formed by RIE using a mask (not illustrated), for example. For example, a fluorine-based (F-based) gas is used as the reactive gas when forming the opening 50S and the opening 50D.

Next, a source electrode 42S is formed on the regrowth layer 41S inside the opening 50S, and a drain electrode 42D is formed on the regrowth layer 41D inside the opening 50D. The source electrode 42S makes contact with the regrowth layer 41S, and the drain electrode 42D makes contact with the regrowth layer 41D. The source electrode 42S makes an ohmic contact with the regrowth layer 41S, and the drain electrode 42D makes an ohmic contact with the regrowth layer 41D. When forming the source electrode 42S and the drain electrode 42D, a metal layer (not illustrated) that forms the source electrode 42S and the drain electrode 42D is formed first. When forming the metal layer, a film formation is performed using a growth mask (not illustrated) having an opening in a region where the metal layer is to be formed, for example, and the growth mask is thereafter removed together with the metal layer (not illustrated) formed thereon. That is, a lift-off is performed.

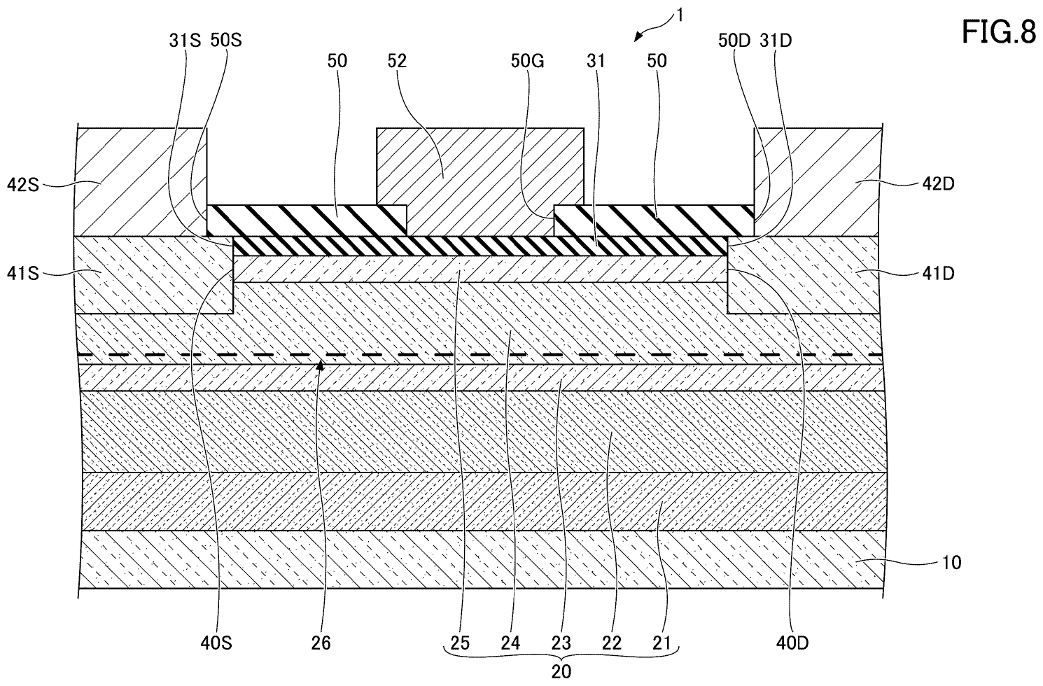

Next, as illustrated in FIG. 8, an opening 50G for a gate is formed in the passivation film 50. The opening 50G can be formed by RIE using a mask (not illustrated), for example. For example, a F-based gas is used as the reactive gas when forming the opening 50G. In the plan view, the opening 50G is formed at a position between the opening 50S and the opening 50D. A portion of the dielectric oxynitride film 31 is exposed via the opening 50G.

Next, a gate electrode 52 making contact with the dielectric oxynitride film 31 via the opening 50G is formed on the passivation film 50. When forming the gate electrode 52, a film formation is performed using a growth mask (not illustrated) having an opening in a region where the gate electrode 52 is to be formed, for example, and the growth mask is thereafter removed together with the metal layer (not illustrated) formed thereon. That is, a lift-off is performed.

The semiconductor device 1 can be manufactured in the manner described above.

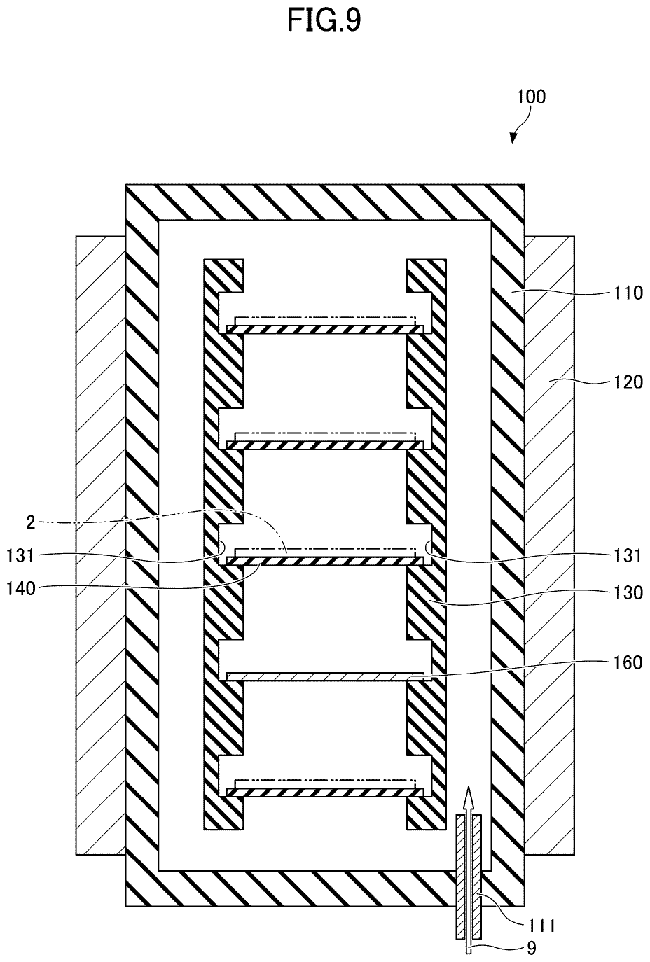

Next, a method for nitriding the dielectric oxide film 39 will be described. FIG. 9 is a cross sectional view illustrating a reaction furnace used for nitriding the dielectric oxide film 39.

As illustrated in FIG. 9, a reaction furnace 100 includes a chamber 110, a nozzle 111, a heater 120, a jig 130, and a substrate holder 140. The reaction furnace 100 is a low pressure chemical vapor deposition (LPCVD) apparatus, for example.

The nozzle 111 for supplying a source gas 9 is provided in the chamber 110. The source gas 9 is a gas mixture of an ammonia (NH₃) gas and a nitrogen gas (N₂), for example. The heater 120 is provided around the chamber 110 and can heat the inside of the chamber 110. The jig 130 is provided inside the chamber 110. The jig 130 has a plurality of recesses 131 configured to support the substrate holders 140, respectively. The substrate 2 is placed on the substrate holder 140. The jig 130 supports the plurality of substrate holders 140 having the substrates 2 placed thereon, respectively, and thus, the nitridation of the dielectric oxide film 39 can be performed simultaneously on the plurality of substrates 2 to form the dielectric oxynitride film 31.

In this example, the chamber 110, the jig 130, and the substrate holder 140 are formed of quartz, and the nozzle 111 is formed of stainless steel. The substrate holder 140 may be formed of silicon. In thermal decomposition of ammonia, quartz does not function as a catalyst, but stainless steel functions as the catalyst. That is, a catalyst metal with respect to the thermal decomposition of ammonia is present at least on a surface of the nozzle 111.

When nitriding the dielectric oxide film 39, a temperature inside the chamber 110 is set in a range of 600° C. or more and 800° C. or less by the heater 120, and a gas mixture of the ammonia gas and the nitrogen gas is supplied into the chamber 110 through the nozzle 111. A flow rate of the ammonia gas is set to 100 sccm or more, and may be set to 200 sccm or more, for example. When the flow rate of the ammonia gas is 100 sccm or more, nitridation of the dielectric oxide film 39 can easily be advanced. In addition, a pressure inside the chamber 110 is set in a range of 40 Pa or more and 120 Pa or less, for example. The temperature inside the chamber 110 may be in a range of 650° C. or more and 750° C. or less. The temperature inside the chamber 110 can be measured using a thermocouple or the like.

The thermal decomposition of the ammonia gas occurs when the ammonia gas makes contact with the stainless steel nozzle 111. Further, oxygen atoms diffuse from the dielectric oxide film 39. As a result, a dinitrogen monoxide (N₂O) gas is generated from nitrogen atoms included in the ammonia gas and the oxygen atoms diffused from the dielectric oxide film 39. Thereafter, the dinitrogen monoxide is thermally decomposed to generate a nitrogen monoxide (NO) gas. Because nitrogen monoxide has a strong nitriding ability, the nitridation of the dielectric oxide film 39 is performed to form the dielectric oxynitride film 31.

In the semiconductor device 1, the dielectric oxynitride film 31 functions as a gate insulating film. The dielectric oxynitride film 31 has a higher insulation and a higher withstand voltage than the dielectric oxide film 39, and a gate leakage can be reduced according to the present embodiment.

Moreover, because the stainless steel nozzle 111 functions as a catalyst with respect to the thermal decomposition of the ammonia gas, the ammonia gas may be used as a nitrogen source to be supplied to the reaction furnace 100, and the dinitrogen monoxide gas and the nitrogen monoxide gas do not need to be supplied to the reaction furnace 100.

In the case where the dinitrogen dioxide gas is supplied to the reaction furnace 100 and the nitridation of the dielectric oxide film 39 is performed by the dinitrogen oxide gas, oxidation and nitridation progress simultaneously, such that a nitrogen concentration in the dielectric oxynitride film 31 may easily become insufficient, or the characteristics of the dielectric oxynitride film 31 may become difficult to control. In addition, a density of an interface state may increase, and a mobility of electrons may decrease. Moreover, an environmental load of the dinitrogen oxide gas is large. Further, although it is conceivable to supply the dinitrogen oxide gas to the reaction furnace 100 and perform the nitridation of the dielectric oxide film 39 by the nitrogen monoxide gas, handling of the nitrogen monoxide gas is difficult because the nitrogen monoxide gas has a high toxicity.

In the present embodiment, although the dinitrogen monoxide gas and the nitrogen monoxide gas are generated inside the reaction furnace 100, these gases are not discharged to the outside, and for this reason, the environmental load and the toxicity do not need to be taken into consideration. In addition, because the nitridation of the dielectric oxide film 39 is performed using the nitrogen monoxide gas generated by the thermal decomposition of the dinitrogen monoxide gas, the dielectric oxide film 39 is hardly oxidized, and the characteristics of the dielectric oxynitride film 31 can easily be controlled.

Because the dielectric oxide film 39 includes at least one element selected from the group consisting of hafnium, lanthanum, and zirconium, the dielectric oxynitride film 31 can easily have a high relative dielectric constant. Further, because the dielectric oxide film 39 includes at least one element selected from the group consisting of silicon and aluminum, the dielectric oxynitride film 31 can easily have a high relative dielectric constant.

The surface of the nitride semiconductor layer 20 opposing the dielectric oxide film 39, that is, the surface of the nitride semiconductor layer 20 opposing the dielectric oxynitride film 31 after the nitridation, has the N polarity, the distance between the channel region 26 and the source electrode 42S and the distance between the channel region 26 and the drain electrode 42D can easily be reduced, thereby facilitating the reduction of the resistance to achieve the low resistance.

An entirety of the entire nozzle 111 does not necessarily have to be formed of stainless steel, and it is sufficient that stainless steel is provided on a portion of the surface of the nozzle 111 which makes contact with the ammonia gas. In addition, a composition of the stainless steel is not particularly limited. The catalyst metal is not limited to stainless steel, and may be any metal which can function as a catalyst with respect to the thermal decomposition of the ammonia gas. Typical examples of the catalyst metal include platinum (Pt), rhodium (Rh), palladium (Pd), and ruthenium (Ru).

Further, the member on which the catalyst metal is provided is not limited to the nozzle 111. For example, the chamber 110 may be formed of a catalyst metal, or a catalyst metal may be provided on an inner surface of the chamber 110. The substrate holder 140 may be formed of a catalyst metal, or the catalyst metal may be provided on a surface of the substrate holder 140. The jig 130 may be formed of a catalyst metal, or the catalyst metal may be provided on a surface of the jig 130. Moreover, a dummy member 160 formed of a catalyst metal may be supported by a part of (that is, some of) the recesses 131 of the jig 130, instead of the substrate holder 140. A member having a catalyst metal provided on a surface of a base, such as a silicon substrate or the like, may be used for the dummy member 160. In any case, the ammonia gas is easily thermally decomposed at the surface where the catalyst metal is provided.

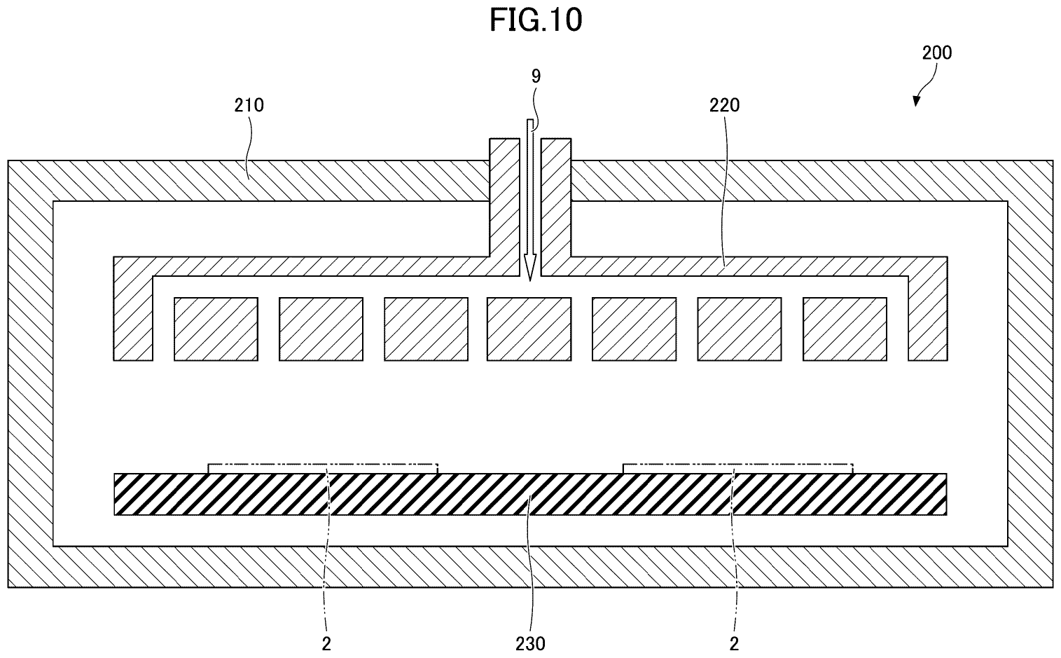

The configuration of the reaction furnace is not particularly limited, and a reaction furnace illustrated in FIG. 10 may be used in place of the reaction furnace 100 illustrated in FIG. 9. FIG. 10 is a cross sectional view illustrating the reaction furnace used for nitriding the dielectric oxide film 39.

As illustrated in FIG. 10, a reaction furnace 200 includes a chamber 210, a shower head 220, and a susceptor 230. The reaction furnace 200 is an MOCVD apparatus, for example.

The shower head 220 for supplying the source gas 9 is provided in the chamber 210. The source gas is a gas mixture of the ammonia gas and the nitrogen gas, for example. The susceptor 230 is provided inside the chamber 210. A plurality of substrates 2 are placed on the susceptor 230 so as to oppose the shower head 220. The susceptor 230 can heat the inside of the chamber 210. The susceptor 230 can directly heat the substrate 2. By placing the plurality of substrates 2 on the susceptor 230, the nitridation of the dielectric oxide film 39 can be performed simultaneously on the plurality of substrates 2 to form the dielectric oxynitride film 31.

In this example, the shower head 220 is formed of stainless steel. The susceptor 230 may be configured such that silicon carbide (SiC) is provided on a surface of a carbon base. In this example, a catalytic metal for the thermal decomposition of ammonia is present at least on the surface of the shower head 220.

When nitriding the dielectric oxide film 39, the temperature inside the chamber 210 is set in a range of 600° C. or more and 800° C. or less by the susceptor 230, and the gas mixture of the ammonia gas and the nitrogen gas is supplied into the chamber 210 through the shower head 220. A flow rate of the ammonia gas is 200 sccm or more, and may be 20000 sccm or more, for example. The pressure inside the chamber 210 is set in a range of 7000 Pa or more and 40000 Pa or less, for example. The temperature inside the chamber 210 may be in a range of 650° C. or more and 750° C. or less. The temperature inside the chamber 210 can be measured using a thermocouple or the like.

When the ammonia gas makes contact with the stainless steel shower head 220, the ammonia gas is thermally decomposed. Oxygen atoms are diffused from the dielectric oxide film 39. As a result, the nitridation of the dielectric oxide film 39 is performed to form the dielectric oxynitride film 31, similar to the case where the reaction furnace 100 described above is used.

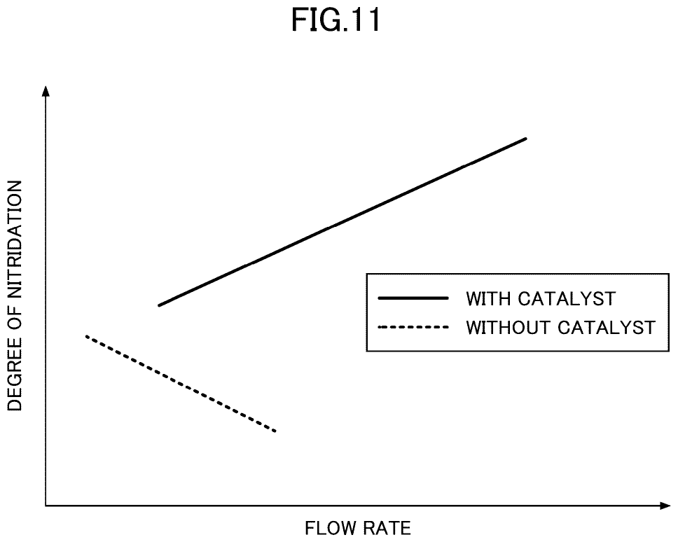

Next, the effect of the catalyst metal will be described. FIG. 11 is a diagram illustrating a relationship between the flow rate of the ammonia gas and a degree of nitridation of the dielectric oxide film. FIG. 11 illustrates the tendency of the relationship for a case where the catalyst metal is present (that is, with catalyst) inside the reaction furnace and the tendency of the relationship for a case where the catalyst metal is not present (that is, without catalyst) inside the reaction furnace.

As illustrated in FIG. 11, in the case without the catalyst metal, the degree of nitridation decreases as the flow rate of the ammonia gas increases. This is because the pressure inside the chamber increases as the flow rate of the ammonia gas increases, and thus, the ammonia gas is less likely to be thermally decomposed due to the Le Chatelier's principle. In contrast, in the case with the catalyst metal, the degree of nitridation increases as the flow rate of the ammonia gas increases. This is because, according to the Le Chatelier's principle, as the flow rate of the ammonia gas increases, the ammonia gas is less likely to be thermally decomposed, but the thermal decomposition of the ammonia gas is more likely to progress due to the action of the catalyst metal. That is, almost all of the supplied amount of the ammonia gas is thermally decomposed and used for nitriding the dielectric oxide film.

Because such a natural phenomenon occurs, according to the present embodiment, the dielectric oxynitride film 31 is formed by supplying the ammonia gas to the reaction furnace, and the gate leakage can be reduced.

If the temperature in the reaction furnace is too high when nitriding the dielectric oxide film 39, the dielectric oxynitride film 31 may become crystallized. On the other hand, if the temperature in the reaction furnace is too low when nitriding the dielectric oxide film 39, it may become difficult to advance the nitridation of the dielectric oxide film 39. When the temperature inside the reaction furnace for nitriding the dielectric oxide film 39 is in a range of 600° C. or more and 800° C. or less, the nitridation of the dielectric oxide film 39 can be facilitated, and crystallization of the dielectric oxynitride film 31 can be prevented.

The polarity of the nitride semiconductor layer is not limited. That is, when the nitride semiconductor layer includes gallium, the surface of the nitride semiconductor layer opposing the dielectric oxide film may have a Ga polarity.

The source gas supplied into the reaction furnace does not need to include the nitrogen gas as long as the ammonia gas is included, but the supply of excess ammonia gas can be prevented by including the nitrogen gas. In addition, when the ammonia gas and the nitrogen gas account for 95 vol % or more of the gases supplied into the reaction furnace, it is easy to prevent the supply of unnecessary gases such as the dinitrogen monoxide gas and the nitrogen monoxide gas. The ammonia gas and the nitrogen gas may account for 97 vol % or more of the gases supplied into the reaction furnace, and the ammonia gas and the nitrogen gas may account for 100 vol % of the gases supplied into the reaction furnace. The reaction furnace may be a rapid thermal annealing (RTA) reaction furnace.

Although the embodiments have been described in detail, the present disclosure is not limited to the specific embodiments, and various modifications and changes can be made within the scope described in the claims.

According to one aspect of the present disclosure, it is possible to reduce the gate leakage.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a semiconductor device, comprising:
forming a dielectric oxide film on a nitride semiconductor layer, the dielectric oxide film having a higher relative dielectric constant than silicon dioxide;
forming a dielectric oxynitride film by nitriding the dielectric oxide film; and
forming a gate electrode on the dielectric oxynitride film,
wherein the forming the dielectric oxynitride film includes:
disposing a substrate including the nitride semiconductor layer and the dielectric oxide film inside a reaction furnace including a catalyst metal therein;
thermally decomposing an ammonia gas inside the reaction furnace to generate a dinitrogen monoxide gas from nitrogen atoms included in the ammonia gas and oxygen atoms diffused from the dielectric oxide film; and
thermally decomposing the dinitrogen monoxide gas to generate a nitrogen monoxide gas.

2. The method for manufacturing the semiconductor device as claimed in claim 1, wherein the dielectric oxide film includes at least one element selected from a group consisting of hafnium, lanthanum and zirconium.

3. The method for manufacturing the semiconductor device as claimed in claim 2, wherein the dielectric oxide film includes at least one element selected from a group consisting of silicon and aluminum.

4. The method for manufacturing the semiconductor device as claimed in claim 1, wherein a surface of the nitride semiconductor layer opposing the dielectric oxide film has a nitrogen polarity.

5. The method for manufacturing the semiconductor device as claimed in claim 1, wherein the forming the dielectric oxynitride film includes setting a temperature inside the reaction furnace in a range of 600° C. or more and 800° C. or less.

6. The method for manufacturing the semiconductor device as claimed in claim 1, wherein the forming the dielectric oxynitride film supplies the ammonia gas into the reaction furnace at a flow rate of 100 sccm or more.

7. The method for manufacturing the semiconductor device as claimed in claim 1, wherein
the reaction furnace includes a nozzle supplied with the ammonia gas, and
the catalyst metal is present at least on a surface of the nozzle.

8. The method for manufacturing the semiconductor device as claimed in claim 1, wherein
the reaction furnace includes a substrate holder on which the substrate is placed, and
the catalyst metal is present at least on a surface of the substrate holder.

9. The method for manufacturing the semiconductor device as claimed in claim 1, wherein
the reaction furnace includes a substrate holder on which the substrate is placed, and a jig configured to support the substrate holder, and
the catalyst metal is present at least on a surface of the jig.

10. The method for manufacturing the semiconductor device as claimed in claim 1, wherein
the reaction furnace includes a substrate holder on which the substrate is placed, a jig configured to support the substrate holder, and a dummy member supported by the jig, and
the catalyst metal is present at least on a surface of the dummy member.

11. The method for manufacturing the semiconductor device as claimed in claim 1, wherein the reaction furnace includes a chamber having the catalyst metal provided at least on an inner surface thereof.

12. The method for manufacturing the semiconductor device as claimed in claim 1, wherein
the reaction furnace includes a shower head supplied with the ammonia gas, and
the catalyst metal is present at least on a surface of the shower head.

13. The method for manufacturing the semiconductor device as claimed in claim 1, wherein the forming the dielectric oxynitride film supplies a nitrogen gas into the reaction furnace together with the ammonia gas.

14. The method for manufacturing the semiconductor device as claimed in claim 13, wherein the ammonia gas and the nitrogen gas account for 95 vol % or more of gases supplied into the reaction furnace by the forming the dielectric oxynitride film.
